(19) United States
(12) Patent Application Publication
(10) Pub. No.: US 2008/0055816 A1
(43) Pub. Date: Mar. 6, 2008

(54) Capacitor of Semiconductor Device and Fabrication Method Thereof

(76) Inventors: HYUNG JIN PARK, Jinju-si (KR); Mun Sub Hwang, Yuseong-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/846,612

(22) Filed: Aug. 29, 2007

(30) Foreign Application Priority Data
Aug. 29, 2006 (KR) 10-2006-0082446

(51) Int. Cl. H01G 4/30; H01L 21/20

(52) U.S. Cl. 361/301.4; 438/396; 257/E21.369

(57) ABSTRACT

Provided are a capacitor of a semiconductor device having an increased capacitance within a minimum area, and a fabrication method thereof. The capacitor includes a first electrode on a substrate, a first insulator on the first electrode, a second electrode on the first insulator, a second insulator on the second electrode where the second insulator is in contact with the first insulator, and a third electrode on the second insulator where the third electrode is in contact with the first electrode. In embodiments, the capacitance can be desirably adjusted within a limited area by alternately overlaying electrodes and insulator layers connected at alternating sides to the electrode or insulator layer below, which makes it possible to design the semiconductor device flexibly and maximize the capacitance.

### CROSS-REFERENCE TO RELATED APPLICATION

The present application claims the benefit under 35 U.S.C. §119 of Korean Patent Application No. 10-2006-0082446, filed Aug. 29, 2006, which is hereby incorporated by reference in its entirety.

### BACKGROUND

Recently, with the development of high integration technology for semiconductor devices semiconductor devices where analog capacitors are integrated together with logic circuits are being researched and developed, and they are being popularly applied to various fields. The analog capacitor used in the logic circuit typically has a polysilicoi-insulator/polysilicon (PIP) structure or metal/insulator/metal (MIM) structure.

Since such PIP or MIM capacitors are independent of bias, unlike metal oxide silicon (MOS) capacitors or junction capacitors, they are widely used in analog products requiring precision of a capacitor.

Since bottom and top electrodes of the MIM capacitor are formed of a metallic material, the MIM capacitor can be fabricated during a process of forming a metal line.

FIG. 1 is a cross-sectional view illustrating a related art MIM capacitor of a semiconductor device.

Referring to FIG. 1, the related art MIM capacitor includes a bottom electrode 11, an insulator 13 and a top electrode 15 which are sequentially stacked on a semiconductor substrate 10 where underlying structures are formed. The bottom and top electrodes 11 and 15 are formed of a metal.

An interlayer dielectric (ILD) layer 17 is formed to a predetermined thickness on the capacitor, and first and second via holes 25 and 27 are formed in the ILD layer 17. Here, the first via hole 25 exposes a predetermined portion of the bottom electrode 11, and the second via hole 27 exposes a predetermined portion of the top electrode 15.

A first plug 21 made of a metallic material is filled into the first via hole 21 and a second plug 23 made of a metallic material is filled into the second via hole 27.

A first metal line 31 and a second metal line 33 are formed on the ILD layer 17. The first metal line 31 is connected to the first plug 21, and the second metal line 33 is connected to the second plug 23. Thus, capacitance signals are inputted to the bottom and top electrodes 11 and 15 of the capacitor through the first and second metal lines 31 and 33, respectively.

However, the related art MIM capacitor of the semiconductor device has a flat, planar structure in which the bottom electrode 11, the insulator 13 and the top electrode 15 are flatly stacked over the substrate 10, as illustrated in FIG. 1. Therefore, to increase the capacitance the bottom electrode 11, the insulator 13, and the top electrode 15 must be extended in their horizontal plane, taking up a larger area.

Moreover, as semiconductor devices are being highly integrated of late, an area where a capacitor occupies is also being reduced in a device. Hence, researches for capacitors having high capacitance despite the same occupation area are essentially needed. Accordingly, studies for a method of improving capacitance by increasing an effective area of a capacitor is being actively conducted.

### BRIEF SUMMARY

Accordingly, in one embodiment of the present invention, a capacitor of a semiconductor device includes: a first electrode on a substrate; a first insulator on the first electrode; a second electrode on the first insulator; a second insulator on the second electrode, where the second insulator is connected to the first insulator at least at a first side; and a third electrode on the second insulator, where the third electrode is connected to the first electrode at least at the first side.

In another embodiment, a method of fabricating a capacitor of a semiconductor device includes: forming a first electrode on a substrate; forming a first insulator on the first electrode; forming a second insulator on the first insulator; forming a second insulator on the second electrode connected to the first insulator; and forming a third electrode on the second insulator connected to the first electrode.

The details of one or more embodiments are set forth in the accompanying drawings and the description below. Other features will be apparent from the description and drawings, and from the claims.

### BRIEF DESCRIPTION OF THE DRAWINGS

FIG. 1 is a cross-sectional view illustrating a related art metal-insulator-metal (MIM) capacitor of a semiconductor device.

FIG. 2 is a cross-sectional view illustrating a capacitor of a semiconductor device according to an embodiment of the present invention.

FIGS. 3A to 3H are cross-sectional views illustrating a method of fabricating a capacitor of a semiconductor device according to an embodiment of the present invention.

FIG. 4 is a cross-sectional view illustrating a capacitor of a semiconductor device according to an embodiment of the present invention.

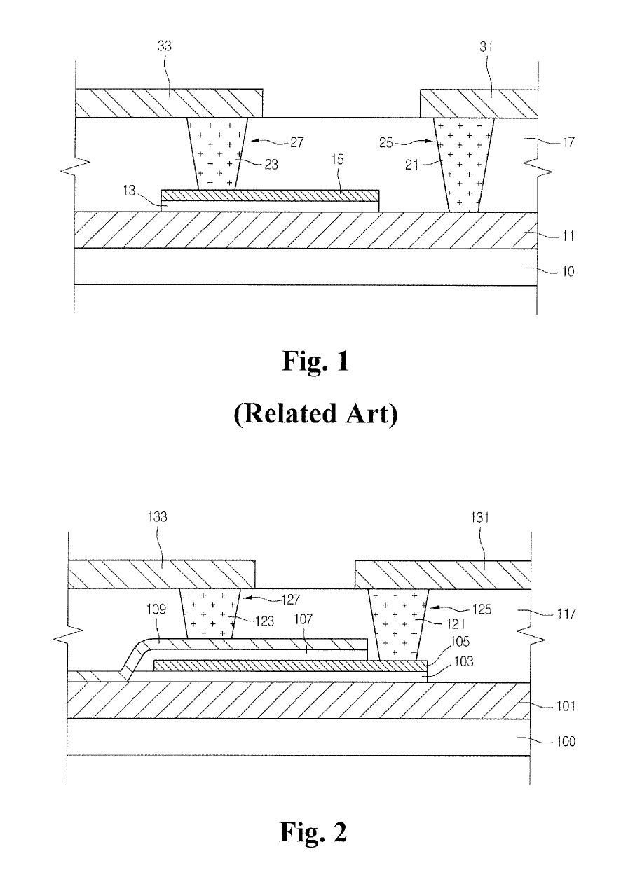

### DETAILED DESCRIPTION

Hereinafter, a capacitor of a semiconductor device and a fabrication method thereof according to embodiments of the present invention will be described in detail with reference to the accompanying drawings.

FIG. 2 is a cross-sectional view illustrating a capacitor of a semiconductor device according to a first embodiment.

Referring to FIG. 2, the capacitor includes a first electrode 101, a first insulator 103, a second electrode 105, a second insulator 107, and a third electrode 109, which are sequentially stacked on a semiconductor substrate 100 where underlying structures having semiconductor components, metal lines, and insulators can be provided.

The first, second, and third electrodes 101, 105 and 109 can be formed of polycrystalline silicon or a metallic material such as titanium (Ti), tantalum (Ta), copper (Cu), aluminum (Al), platinum (Pt), ruthenium (Ru), iridium (Ir), rhodium (Rh), or osmium (Os).

The first and second insulators 103 and 107 can be formed of, for example, a high-dielectric-constant material, an oxide, or a nitride. In an embodiment, the first and second insulators 103 and 107 may have a multi-stacked structure of an oxide-nitride-oxide (ONO) structure.

As shown in FIG. 2, the first and third electrodes 101 and 109 are electrically connected to each other at one side thereof, and the first and second insulators 103 and 107 are also connected to each other at the one side.

Thus, the first and third electrodes 101 and 109 receive the same capacitor signal, whereas the second electrode 105 receives a different capacitor signal.

The first insulator 103 between the first and second electrodes 101 and 105 accumulates charges to some extent, and the second insulator 107 between the third and second electrodes 109 and 105 also accumulates charges.

The first and second insulators 103 and 107 are connected to each other, as described above.

Since the third electrode 109 overlaps the first electrode 101 while the second electrode 105 is interposed therebetween, a total electrode area becomes almost twice greater than that of the related art capacitor where only the two electrodes are flatly disposed, thus allowing the capacitor to have higher capacitance.

Therefore, a capacitor according to an embodiment of the present invention can exhibit a high capacitance in spite of its minimum occupation area.

Generally, the capacitance can be calculated by the following equation.

$$C = ɛ \frac{S}{d} [ F ] ,$$

where C, ε, S and d denote a capacitance (unit: F), a dielectric constant, an effective area of an electrode, and a space between electrodes, respectively.

Since the effective area S increases because of the first and third electrodes 101 and 109 above and below the second electrode 105, it can be appreciated that the capacitance increases in proportion to the increase in the effective area S.

Alternatively, the capacitance may be controlled by adjusting sizes of the third electrode 109 and the second insulator 107.

An interlayer dielectric (ILD) layer 117 with a predetermined thickness can be disposed on the capacitor. A first via hole 127 and a second via hole 125 can be provided in the ILD layer 117. According to embodiments, the first via hole 127 exposes a predetermined portion of the first electrode 101 or the third electrode 109, and the second via hole 125 exposes a predetermined portion of the second electrode 105. In one embodiment, the first via hole 127 exposes a portion of the third electrode 109.

A first plug 123 made of a metallic material can be provided in the first via hole 127, and a second plug 121 made of a metallic material can be provided in the second via hole 125.

A first metal line 133 connected to the first plug 122 and a second metal line 131 connected to the second plug 121 are disposed on the ILD layer 117.

A method of fabricating the capacitor of a semiconductor device according to an embodiment of the present invention having the above structure will be explained in detail below.

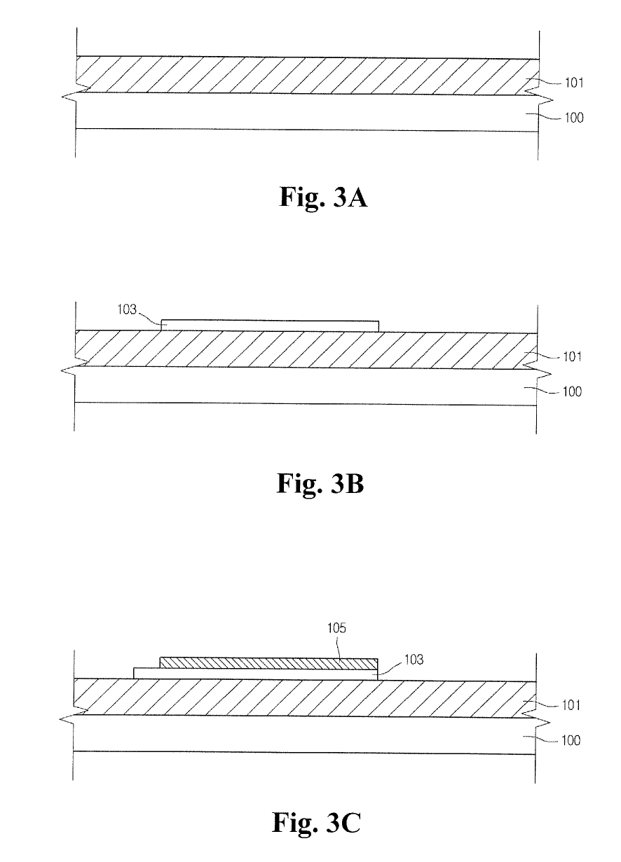

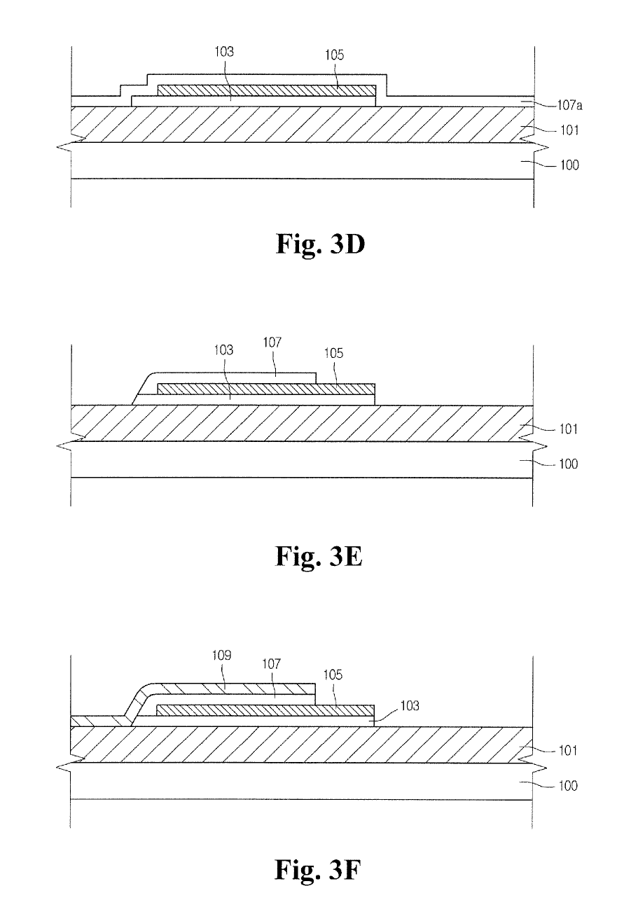

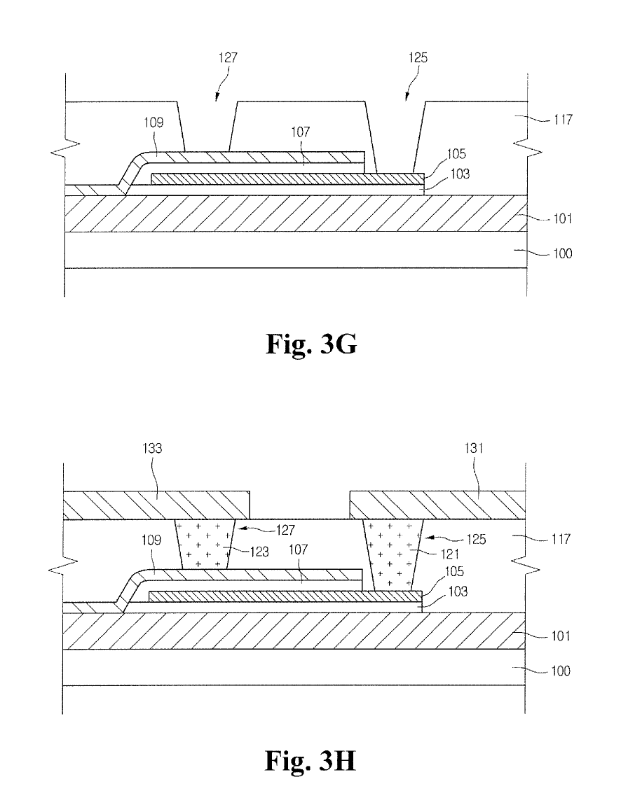

FIGS. 3A to 3H are cross-sectional views illustrating a method of fabricating a capacitor of a semiconductor device according to an embodiment.

Referring to FIG. 3A, a first electrode 101 can be formed on a semiconductor substrate 100 where underlying structures such as semiconductor components, metal lines and ILD layers may be formed.

The first electrode 101 can be formed of polycrystalline silicon or metallic material such as Ti, Ta, Cu, Al, Pt, Ru, Ir, Rh, or Os.

Thereafter, referring to FIG. 3B, a first insulator 103 can be formed on the first electrode 101.

The first insulator 103 can be formed of a high-dielectric-constant material, an oxide or a nitride. In one embodiment, the first insulator 103 can have a multi-stacked structure of an ONO structure.

Then referring to FIG. 3C, a second electrode 105 can be formed on the first insulator 103.

According to embodiments of the present invention, the second electrode 105 is formed smaller in area than the first insulator 103 to partially expose the top surface of the first insulator 103.

Referring to FIGS. 3D and 3E, an insulating material 107a can be formed on an entire surface of the semiconductor substrate 100 where the first electrode 101, the second electrode 105 and the first insulator 103 are formed. Then, the insulating material 107a can be patterned into a predetermined shape to form a second insulator 107 on the second electrode 105.

Preferably, the second insulator 107 may be formed of the same dielectric material as the first insulator 103, but embodiments are not limited thereto.

The second insulator 107 extends over the exposed top surface of the first insulator 103, whereby the second insulator 107 contacts the first insulator 103. In this case, the first and second insulators 103 and 107 can form a one-side opened rectangular shape, as illustrated in FIG. 3E.

Next, referring to FIG. 3F, a third electrode 109 can be formed on the second insulator 107 and contacting the first electrode 101.

The third electrode 109 can be formed of polycrystalline silicon or metallic material such as Ti, Ta, Cu, Al, Pt, Ru, Tr, Rh, or Os.

Here, the second electrode 105 and the third electrode 109 are not in contact with each other. Rather, the third electrode 109 extends over the second insulator 107 to one end of the first electrode 101 so that the third electrode 109 can be electrically connected to the first electrode 101, while being separated from the second electrode 105 by the second insulator 107.

As a result, the first and third electrodes 101 and 109 are electrically connected at a side thereof, and the first and second insulators 103 and 107 are also connected to each other at the side.

Thus, the first and third electrodes 101 and 109 can receive the same capacitor signal, whereas the second electrode 105 receives another capacitor signal.

The first insulator 103 between the first and second electrodes 101 and 105 accumulates charges to some extent, and the second insulator 107 between the third and second electrodes 109 and 105 also accumulates charges.

Since the third electrode 109 overlaps the first electrode 101 while the second electrode 105 is interposed therebetween, a total electrode area becomes almost twice greater than that of the related art capacitor where only the two electrodes are flatly disposed, thus allowing the capacitor to have higher capacitance.

Therefore, the capacitor can exhibit a high capacitance in spite of its minimum occupation area.

Referring to FIG. 3G, an ILD layer 117 can be formed to a predetermined thickness on the entire surface of the semiconductor substrate 100 where the first, second, and third electrodes 101, 105 and 109, and the first and second insulators 103 and 107 are formed. A first via hole 127 and a second via hole 125 can be formed in the ILD layer 117. Herein, the first via hole 127 exposes a predetermined portion of the first electrode 101 or the third electrode 109, and the second via hole 125 exposes a predetermined portion of the second electrode 105. FIG. 3G shows the first via hole 127 exposing a predetermined portion of the third electrode 109.

The ILD layer 117 can be formed of a low-dielectric-constant material, for example, plasma enhanced tetra ethyl ortho silicate (PE-TEOS), undoped silicate glass (USG) or fluorine silicate glass (FSG).

Then, referring to FIG. 3H, a first plug 123 made of metal can be filled in the first via hole 127, and a second plug 121 made of metal can be filed in the second via hole 125.

Although not shown, a barrier layer can be formed on the ILD layer 117 having the first and second via holes 127 and 125 therein using an insulating material having an etch selectivity with respect to the ILD layer 117. Then, in one embodiment, a tungsten layer can be formed so as to fill the first and second via holes 127 and 125.

Thereafter, the tungsten layer can be planarized by a chemical mechanical polishing (CMP) until the ILD layer 117 is exposed, thus forming the first and second plugs 123 and 121 filling the first and second via holes 127 and 125.

According to various embodiments, the first and second plugs 123 and 121 can be formed of a metal such as copper, titanium/titanium nitride, aluminum, or tungsten.

In an embodiment, a metal layer can be formed on the ILD layer 117, and patterned to a predetermined configuration to form first and second metal lines 133 and 131. The first and second metal lines 133 and 131 apply voltages to the third electrode 109 (and the first electrode 101) and the second electrode 105 through the first and second plugs 123 and 121, respectively.

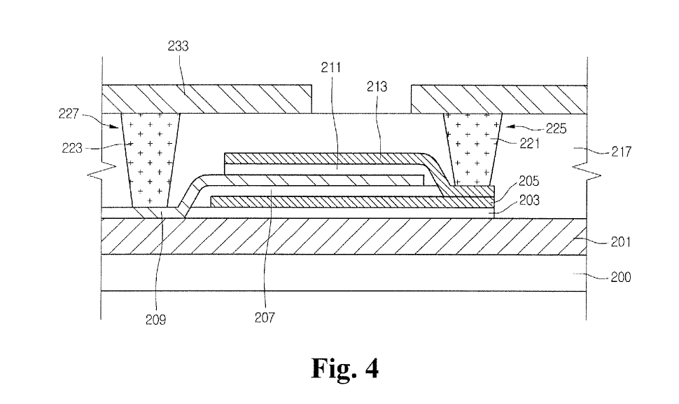

FIG. 4 is a cross-sectional view illustrating a capacitor of a semiconductor device according to a second embodiment.

Referring to FIG. 4, the capacitor includes a first electrode 201, a first insulator 203, a second electrode 205, a second insulator 207, a third electrode 209, a third insulator 211 and a fourth electrode 213 which are sequentially stacked on a semiconductor substrate 200 where underlying structures having semiconductor components, metal lines and insulators may be provided.

The first and third electrodes 201 and 209 are electrically connected to each other.

The first, second, and third insulators 203, 207 and 211 are mutually connected.

The second electrode 205 and the fourth electrode 213 are electrically connected to each other.

The first and third electrodes 201 and 209 are not in direct contact with the second and fourth electrodes 205 and 213.

The first insulator 203 is provided between the first electrode 201 and the second electrode 205, the second insulator 207 is provided between the second electrode 205 and the third electrode 209, and the third insulator 211 is provided between the third electrode 209 and the fourth electrode 213.

The first and second insulators 203 and 207 can be in contact with each other at one side of the capacitor, and likewise the third and third electrodes 201 and 209 are connected to each other at the one side of the capacitor in a similar fashion to the first embodiment. In addition, the second and third insulators 207 and 211 can be in contact with each other at the other side of the capacitor, and likewise the second and fourth electrodes 205 and 213 are connected to each other at this other side of the capacitor.

Thus, the first and third electrodes 201 and 209 can receive a first capacitor signal through a first metal line 233 and plug 223, and the second and fourth electrodes 205 and 213 can receive a second capacitor signal through a second metal line and plug 221.

Here, since the first, second, third, and fourth electrodes 201, 205, 209 and 213 are alternately disposed over the substrate 200 such that they overlap one another with the insulators interposed thereamong, the total electrode area becomes almost three times greater than that of the related art capacitor where only two electrodes are flatly disposed. Thus the capacitor according to embodiments of the present invention can have a much higher capacitance than the related art.

Therefore, the capacitor can exhibit a high capacitance in a minimum occupation area.

In the semiconductor device according to embodiments of the present invention, the capacitance can be increased because the capacitor has a maximum surface area even within a minimum space. In addition, the capacitance of the capacitor can be desirably adjusted within a limited area, which makes it possible to design the semiconductor device flexibly and maximize the capacitance.

Furthermore, according to an embodiment, it is possible to greatly improve the capacitance of the capacitor to meet the needs of developments and researches for highly integrated, small-sized, up-to-date products such as dynamic random access memories (DRAMs), thus accelerating the developments for the semiconductor devices.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A capacitor of a semiconductor device, comprising:
a first electrode on a substrate;
a first insulator on the first electrode;
a second electrode on the first insulator;
a second insulator on the second electrode and in contact with the first insulator; and
a third electrode on the second insulator and in contact with the first electrode.

2. The capacitor according to claim 1, wherein the second electrode is smaller in area than the first insulator.

3. The capacitor according to claim 1, wherein the first and second insulators comprise the same dielectric material.

4. The capacitor according to claim 1, wherein the third electrode and the second insulator expose a predetermined portion of the second electrode.

5. The capacitor according to claim 1, wherein the first insulator is larger in area than the second electrode and extends to one side.

6. The capacitor according to claim 1, further comprising:
a third insulator on the third electrode and in contact with the second insulator; and
a fourth electrode on the third insulator and in contact with the second electrode.

7. The capacitor according to claim 6, further comprising:
an interlayer dielectric layer on the substrate, the interlayer dielectric layer having a first plug electrically connected to the first electrode and a second plug electrically connected to the second electrode;
a first metal line on the interlayer dielectric layer contacting the first plug; and
a second metal line on the interlayer dielectric layer contacting the second plug.

8. The capacitor according to claim 6, wherein the first, second, and third electrodes comprise at least one selected from the group consisting of titanium (Ti), tantalum (Ta), copper (Cu), aluminum (Al), platinum (Pt), ruthenium (Ru), iridium (Ir), rhodium (Rh) and osmium (Os).

9. The capacitor according to claim 6, wherein the second insulator is connected to the first insulator at least at a first side;
wherein the third electrode is connected to the first electrode at least at the first side;
wherein the third insulator is connected to the first insulator at least at a second side; and
wherein the fourth electrode is connected to the second electrode at least at the second side.

10. The capacitor according to claim 1, wherein the first and second insulators comprise at least one of an oxide layer and a nitride layer.

11. The capacitor according to claim 1, wherein the first and second insulators comprise a multi-stacked structure of oxide-nitride-oxide (ONO).

12. The capacitor according to claim 1, wherein the second insulator is connected to the first insulator at least at a first side; and
wherein the third electrode is connected to the first electrode at least at the first side.

13. A method of fabricating a capacitor of a semiconductor device, the method comprising:
forming a first electrode on a substrate;
forming a first insulator on the first electrode;
forming a second electrode on the first insulator;
forming a second insulator on the second electrode in contact with the first insulator; and
forming a third electrode on the second insulator in contact with the first electrode.

14. The method according to claim 13, wherein the second electrode is formed smaller in area than the first insulator.

15. The method according to claim 13, further comprising:
forming a third insulator on the third electrode and in contact with the second insulator; and
forming a fourth electrode on the third insulator and in contact with the second electrode.

16. The capacitor according to claim 15, wherein the second insulator is connected to the first insulator at least at a first side;
wherein the third electrode is connected to the first electrode at least at the first side;
wherein the third insulator is connected to the first insulator at least at a second side; and
wherein the fourth electrode is connected to the second electrode at least at the second side.

17. The method according to claim 13, wherein the first insulator is formed greater in area than the second electrode.

18. The capacitor according to claim 13, wherein the second insulator is connected to the first insulator at least at a first side; and
wherein the third electrode is connected to the first electrode at least at the first side.

19. The method according to claim 13, further comprising, after forming the third electrode:
forming an interlayer dielectric layer on an entire surface of the substrate;
patterning the interlayer dielectric layer to form a first via hole exposing a portion of at least one of the first and third electrodes and a second via hole exposing a portion of the second electrode
forming a plug layer such that the first and second via holes are filled with a metal, and polishing the plug layer by a chemical mechanical polishing (CMP) to form a first plug and a second plug in the first via hole and the second via hole, respectively; and
forming a metal layer on the interlayer dielectric layer, and patterning the metal layer to form a first metal line connected to the first plug and a second metal line connected to the second plug.

20. The method according to claim 19, wherein the first and second plugs comprise at least one selected from the group consisting of copper, titanium, titanium nitride, aluminum, and tungsten.
